(19) United States
(12) Patent Application Publication
(10) Pub. No.: US 2026/0114012 A1
(43) Pub. Date: Apr. 23, 2026

(54) SEMICONDUCTOR DEVICE

(71) Applicant: Samsung Electronics Co., Ltd., Suwon-si (KR)

(72) Inventors: Dowon SONG, Suwon-si (KR); Heonjong SHIN, Suwon-si (KR); Seowoo NAM, Suwon-si (KR); June Young PARK, Suwon-si (KR); Hyeyoung PARK, Suwon-si (KR); Sunggyu HAN, Suwon-si (KR)

(21) Appl. No.: 19/185,845

(22) Filed: Apr. 22, 2025

(30) Foreign Application Priority Data
Oct. 23, 2024 (KR) 10-2024-0145455

(51) Int. Cl. H10D 64/23; H10D 30/00; H10D 30/01

(52) U.S. Cl. CPC H10D 64/254; H10D 30/0198; H10D 30/501

(57) ABSTRACT

A semiconductor device may include a lower wiring pattern extending in a first direction, a lower insulating layer disposed on the lower wiring pattern, a channel pattern disposed on the lower insulating layer, a gate electrode surrounding the channel pattern and extending in a second direction intersecting the first direction, a first source/drain pattern disposed on a first side surface of the channel pattern, wherein the first source/drain pattern comprises a first lower region and a first middle region, and the first lower region is disposed closer to the lower insulating layer than the first middle region, a second source/drain pattern disposed on a second side surface of the channel pattern. The second source/drain pattern comprises a second lower region and a second middle region, and the second lower region is disposed closer to the lower insulating layer than the second middle region. The semiconductor device further include a connection pattern formed through the lower insulating layer and connecting the lower wiring pattern and the first source/drain pattern. One end of the connection pattern is in contact with the first lower region. A concentration of a dopant in the second lower region is greater than a concentration of a dopant in the second middle region. The second source/drain pattern is disposed in a source/drain trench, and a lowermost end of the source/drain trench is located at a central portion of a bottom surface of the source/drain trench. The first and second middle regions are located at higher height levels than the first and second lower regions, and the first and second lower regions are located at higher height levels than the bottom surface of the source/drain trench.

### CROSS-REFERENCE TO RELATED APPLICATION

This application claims priority to Korean Patent Application No. 10-2024-0145455, filed in the Korean Intellectual Property Office on Oct. 23, 2024, the entire contents of which are hereby incorporated by reference.

### BACKGROUND

### Field

The present disclosure relates to a semiconductor device.

### Description of Related Art

A semiconductor device is a core component used to control or amplify an electrical signal in an electronic device, and various types of semiconductor devices may be manufactured. For example, memory devices may be used primarily to store and retrieve data, while non-memory devices may be used to control or amplify electrical signals. The semiconductor device is a core component of an electronic device and plays an important role in various fields including computers, communication equipment, consumer electronics, etc.

With the development of industry, the performance and function requirements of electronic devices are also increasing. Accordingly high-performance characteristics of semiconductor devices are essentially required, and the integration density of the semiconductor devices is increasing to meet these requirements. Various methods for forming semiconductor devices having excellent performance and improved integration density are being studied.

### SUMMARY

In order to address one or more problems (e.g., the problems described above and/or other problems not explicitly described herein), the present disclosure provides a semiconductor device with improved electrical characteristics and reliability.

According to some embodiments of the present disclosure, by adjusting the concentration of the dopant in a first lower filling film to be greater than the concentration of the dopant in a first middle filling film, the contact resistance between a first source/drain pattern and a lower source/drain contact can be reduced. As a result, electrical characteristics and reliability of the semiconductor device can be improved.

According to some embodiments of the present disclosure, a semiconductor device may include a lower wiring pattern extending in a first direction, a lower insulating layer disposed on the lower wiring pattern, a channel pattern disposed on the lower insulating layer, a gate electrode surrounding the channel pattern and extending in a second direction intersecting the first direction, a first source/drain pattern disposed on a first side surface of the channel pattern. The first source/drain pattern comprises a first lower region and a first middle region. The semiconductor device may include a second source/drain pattern disposed on a second side surface of the channel pattern. The second source/drain pattern comprises a second lower region and a second middle region. The semiconductor device further includes a connection pattern formed through the lower insulating layer and connecting the lower wiring pattern and the first source/drain pattern. One end of the connection pattern is in contact with the first lower region. A concentration of a dopant in the second lower region is greater than a concentration of a dopant in the second middle region. The second source/drain pattern is disposed in a source/drain trench, and a lowermost end of the source/drain trench is located at a central portion of a bottom surface of the source/drain trench. The first and second middle regions are located at higher height levels than the first and second lower regions, and the first and second lower regions are located at higher height levels than the bottom surface of the source/drain trench.

According to some embodiments of the present disclosure, a semiconductor device may include a lower wiring pattern extending in a first direction, a lower insulating layer disposed on the lower wiring pattern, a plurality of sheet patterns disposed on the lower insulating layer and spaced apart from each other in a direction perpendicular to an upper surface of the lower wiring pattern, a gate electrode surrounding the plurality of sheet patterns and extending in a second direction intersecting the first direction, a first source/drain pattern disposed on a side of the plurality of sheet patterns. The first source/drain pattern comprising a first lower region, a first middle region and a first upper region, which are sequentially stacked. The semiconductor device further includes a second source/drain pattern disposed spaced apart from the first source/drain pattern. The second source/drain pattern comprises a second lower region, a second middle region and a second upper region, which are sequentially stacked. The semiconductor device further includes a first semiconductor pattern disposed below the second source/drain pattern, and a connection pattern formed through the lower insulating layer and connecting the lower wiring pattern and the first source/drain pattern. The connection pattern is in contact with the first lower region. A concentration of a dopant in the first lower region is greater than a concentration of a dopant in the first middle region.

According to some embodiments of the present disclosure, a semiconductor device may include, a lower wiring pattern extending in a first direction, a lower insulating layer disposed on the lower wiring pattern, a plurality of sheet patterns disposed on the lower insulating layer and spaced apart from each other in a direction perpendicular to an upper surface of the lower wiring pattern, a gate electrode surrounding the plurality of sheet patterns and extending in a second direction intersecting the first direction, a first source/drain pattern disposed on a side of the plurality of sheet patterns, wherein the first source/drain pattern includes a first liner region, a first lower region, a first middle region, and a first upper region, wherein the first lower region, the first middle region, and the first upper region are sequentially stacked on the first liner region, a second source/drain pattern disposed spaced apart from the first source/drain pattern, wherein the second source/drain pattern includes a second liner region, and a second lower region, a second middle region, and a second upper region, wherein the second lower region, the second middle region, and the second upper region sequentially stacked on the second liner region, a semiconductor pattern disposed below the second source/drain pattern, and a connection pattern formed through the lower insulating layer and connecting the lower wiring pattern and the first source/drain pattern, wherein one end of the connection pattern is disposed on the first lower region, a concentration of a dopant in the first upper region is greater than a concentration of a dopant in the first middle region, a concentration of a dopant in the first lower region is greater than the concentration of the dopant in the first middle region, and the concentration of the dopant in the first lower region is the same as a concentration of a dopant in the second lower region. The first lower region is formed in a lower portion of a space within the first liner. The second lower region is formed in a lower portion of a space within the second liner.

### BRIEF DESCRIPTION OF THE DRAWINGS

The above and other embodiments and features of the present invention will become more apparent by describing in detail example embodiments thereof with reference to the attached drawings, in which:

FIG. 1 is an example plan view provided to explain a semiconductor device according to some embodiments;

FIG. 2 is a cross-sectional view taken along line A-A of FIG. 1;

FIG. 3 is a diagram provided to explain a semiconductor device according to some embodiments;

FIG. 4 is a diagram provided to explain a semiconductor device according to some embodiments;

FIG. 5 is an enlarged view provided to explain a region Q1 of FIG. 4;

FIG. 6 is a diagram provided to explain a semiconductor device according to some embodiments;

FIG. 7 is a diagram provided to explain a semiconductor device according to some embodiments;

FIG. 8 is a diagram provided to explain a semiconductor device according to some embodiments;

FIG. 9 is a diagram provided to explain a semiconductor device according to some embodiments;

FIG. 10 is a diagram provided to explain a semiconductor device according to some embodiments;

FIG. 11 is a diagram provided to explain a semiconductor device according to some embodiments;

FIGS. 12 to 22 are diagrams illustrating intermediate stages, which are provided to explain a method for manufacturing a semiconductor device according to some embodiments.

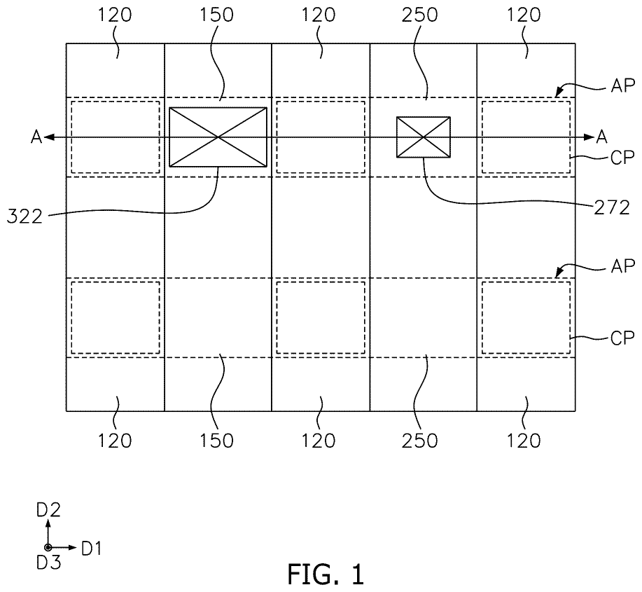

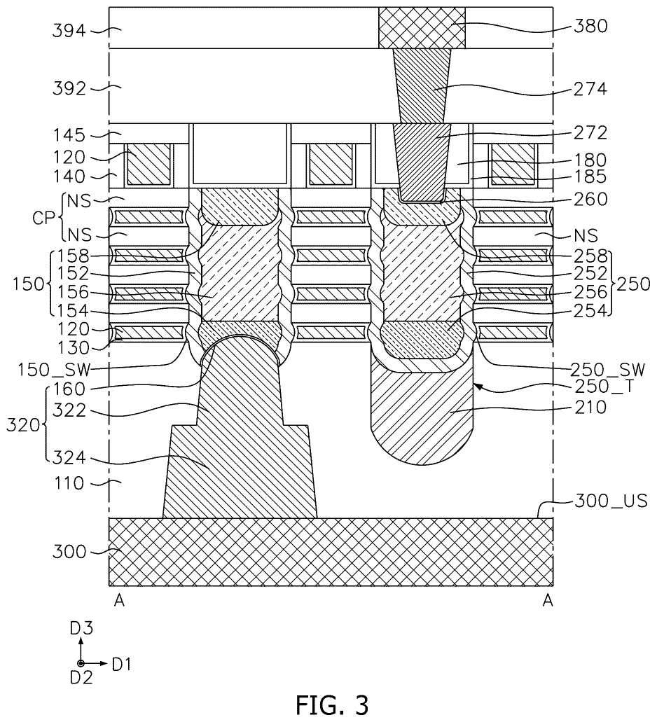

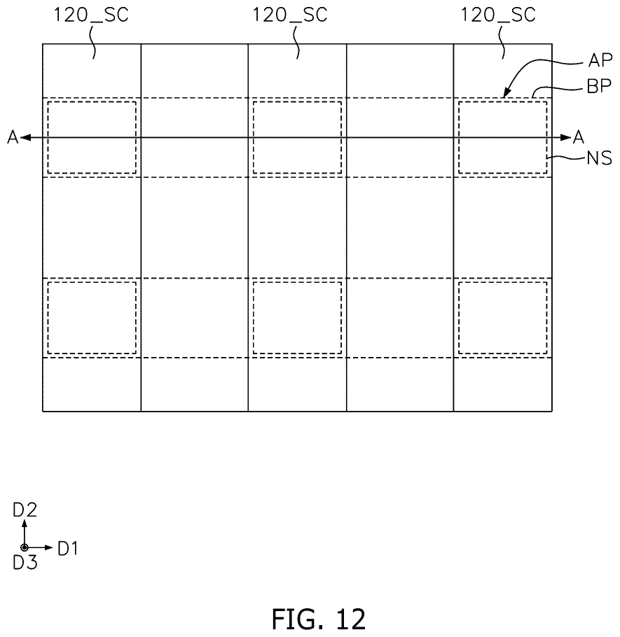

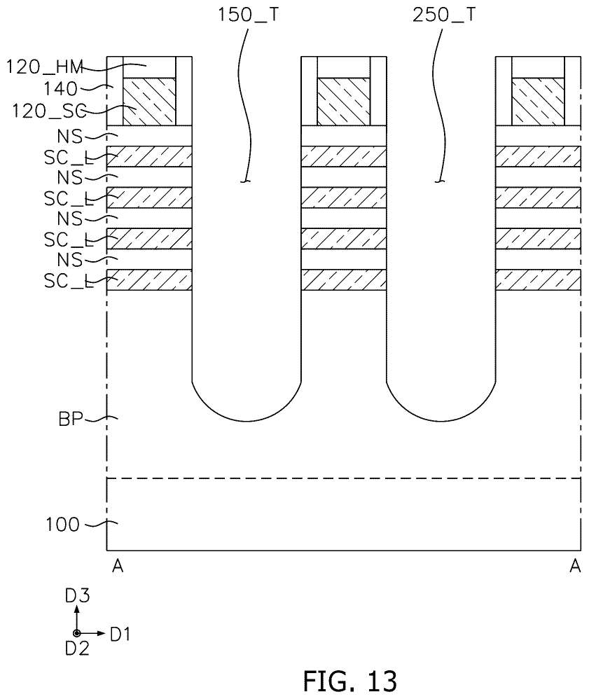

FIGS. 3, 4 and 6 to 11 are cross-sectional views taken along line A-A of FIG. 1, and FIGS. 13 to 22 are cross-sectional views taken along line A-A of FIG. 12.

### DETAILED DESCRIPTION

Hereinafter, a semiconductor device and a method for manufacturing the same according to some embodiments of the present invention will be described in detail with reference to the drawings.

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second”in the specification or another claim).

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially”may be used herein to emphasize this meaning.

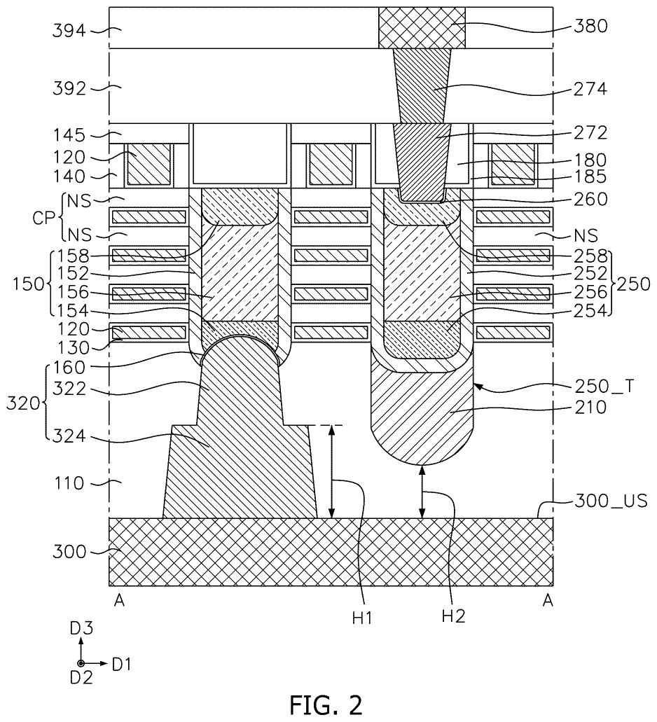

FIG. 1 is an example plan view provided to explain a semiconductor device according to some embodiments. FIG. 2 is a cross-sectional view taken along line A-A of FIG. 1. To enhance clarity in understanding the drawings, any components and related configurations other than an active region AP, a gate electrode 120, a first source/drain pattern 150, a second source/drain pattern 250, an upper source/drain contact 272, and a lower source/drain contact 322 in FIG. 1 are omitted.

Referring to FIGS. 1 and 2, a semiconductor device according to some embodiments may include a lower insulating layer 110, the gate electrode 120, a gate insulating film 130, a gate spacer 140, a gate capping pattern 145, a channel pattern CP, the first source/drain pattern 150, the second source/drain pattern 250, a semiconductor pattern 210, a connection structure 320, a lower wiring 300, the upper source/drain contact 272, an upper via 274, etc.

The semiconductor device according to some embodiments may include a MOSFET, and more specifically, may include a gate-all-round (GAA) transistor. For example, the semiconductor device may be or include a three-dimensional multi-stack semiconductor device referred to as a multi-bridge channel FET (MBCFET). However, embodiments are not limited thereto. For example, the semiconductor device may include a fin-type transistor (FinFET) including a fin-type pattern-shaped channel region.

For example, the lower insulating layer 110 may include at least one of silicon oxide, silicon nitride, silicon oxynitride, and a low-k material. For example, the low-k material may include fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutoxysiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or a combination thereof. However, embodiments are not limited thereto.

The active region AP may be disposed on the lower insulating layer 110. The active region AP may extend in a first direction D1. The active region AP may be disposed to be spaced apart from the adjacent active region AP in a second direction D2. In this case, the first direction D1 is a direction intersecting the second direction D2. Each of the first and second directions D1 and D2 may be a direction parallel to an upper surface 300_US of the lower wiring 300.

A channel pattern CP may be disposed in the active region AP. In some embodiments, the channel pattern CP may include a plurality of sheet patterns NS.

The plurality of sheet patterns NS may be disposed on the lower insulating layer 110. The plurality of sheet patterns NS may be spaced apart from the lower insulating layer 110 in a third direction D3. Each of the sheet patterns NS may be spaced apart from each other in the third direction D3. The third direction D3 may be a direction intersecting each of the first and second directions D1 and D2. The third direction D3 may be a direction perpendicular to the upper surface 300 US of the lower wiring 300. The sheet pattern NS may have a nanosheet shape. Although it is illustrated that there are four sheet patterns NS, embodiments are not limited thereto.

The sheet pattern NS may include one of an elemental semiconductor material such as silicon (Si), silicon germanium (SiGe), a group IV-IV compound semiconductor, or a group III-V compound semiconductor.

For example, the group IV-IV compound semiconductor may be a binary compound or a ternary compound including at least two or more of carbon (C), silicon (Si), germanium (Ge), and tin (Sn).

For example, the group III-V compound semiconductor may be one of a binary compound, a ternary compound, or a quaternary compound formed by a combination of at least one of aluminum (Al) or gallium (Ga), and indium (In) as a group III element and one of phosphorus (P), arsenic (As), and antimony (Sb) as a group V element.

A field insulating film (not shown) may be disposed between active regions AP adjacent to each other in the second direction D2. The field insulating film may be disposed between adjacent lower insulating layers 110. The field insulating film may extend in the first direction D1. For example, the field insulating film may include oxide, nitride, nitride oxide, or a combination thereof. In some embodiments, the field insulating film may include a plurality of films.

The gate electrode 120 may extend on the lower insulating layer 110 in the second direction D2. The gate electrode 120 may intersect the active region AP. The gate electrode 120 may be disposed on the channel pattern CP. The gate electrode 120 may be spaced apart from the adjacent gate electrode 120 in the first direction D1. The gate electrode 120 may surround the plurality of sheet patterns NS. The gate electrode 120 may surround four surfaces of the sheet pattern NS. For example, the gate electrode 120 may surround an upper surface, a lower surface, and both side surfaces of the sheet pattern NS as viewed from the first direction D1. The upper and lower surfaces of the sheet pattern NS may refer to surfaces intersecting the third direction D3. As viewed from the second direction D2, both side surfaces of the sheet pattern NS may refer to surfaces intersecting the second direction D2.

The gate electrode 120 may include an upper gate electrode and a lower gate electrode. The lower gate electrode may be disposed between the sheet patterns NS adjacent to each other in the third direction D3. The lower gate electrode may be disposed between the plurality of sheet patterns NS, and may be disposed between the lower insulating layer 110 and the sheet pattern NS disposed at the lowermost position among the plurality of sheet patterns NS. The upper gate electrode may be disposed on the sheet pattern NS disposed at the uppermost position among the plurality of sheet patterns NS. In some embodiments, the upper gate electrode may include a plurality of layers. For example, the upper gate electrode may include a plurality of films including a work function adjustment film.

In some embodiments, the plurality of sheet patterns NS may be disposed in the active region AP, and the gate electrode 120 may include a plurality of lower gate electrodes. For example, in a cross-sectional view, the plurality of lower gate electrodes may be spaced apart from each other by the plurality of sheet patterns NS. In this case, the number of lower gate electrodes may be proportional to the number of sheet patterns NS disposed in the active region AP. The number of lower gate electrodes may be the same as the number of sheet patterns NS. For example, as illustrated in FIG. 2, the number of lower gate electrodes may be four, which may be the same as the number of sheet patterns NS. However, embodiments are not limited thereto.

The gate electrode 120 may include at least one of a metal, a metal alloy, a conductive metal nitride, a metal silicide, a doped semiconductor material, a conductive metal oxide, or a conductive metal oxynitride. For example, the gate electrode 120 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof, but embodiments are not limited thereto. The conductive metal oxide and the conductive metal oxynitride may include an oxidized form of the material described above, but is not limited thereto.

The gate insulating film 130 may be disposed between the gate electrode 120 and the plurality of sheet patterns NS, between the gate electrode 120 and the lower insulating layer 110, between the gate electrode 120 and the first source/drain pattern 150, and between the gate electrode 120 and the second source/drain pattern 250. Specifically, the gate insulating film 130 may be disposed between the upper gate electrode and the sheet pattern NS disposed at the uppermost position among the plurality of sheet patterns NS. The gate insulating film 130 may be disposed between the lower gate electrode and the sheet pattern NS. The gate insulating film 130 may surround the sheet pattern NS. The gate insulating film 130 may extend along the upper and lower surfaces of the sheet pattern NS in the first direction D1.

In some embodiments, the gate insulating film 130 may include a plurality of films. For example, the gate insulating film 130 may include an interfacial insulating film and a high-k insulating film. For example, the interfacial insulating film may include silicon oxide. The high-k insulating film may include a high-k material having a greater dielectric constant than the interface insulating film. For example, the high-k insulating film may include at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

The gate spacer 140 may be disposed on a side surface of the upper gate electrode. For example, the gate spacer 140 may extend along a side surface of the gate electrode in the second direction D2. The gate spacer 140 may not be positioned between the lower insulating layer 110 and the sheet pattern NS. The gate spacer 140 may not be positioned between the sheet patterns NS adjacent to each other in the third direction D3.

For example, the gate spacer 140 may include at least one of silicon nitride (SiN), silicon nitride oxide (SiON), silicon oxide (SiO2), silicon oxycarbonitride (SiOCN), silicon boron nitride (SiBN), silicon oxide boron nitride (SiOBN), silicon oxycarbide (SiOC), or a combination thereof. Although it is illustrated that the gate spacer 140 is a single film, it is only for convenience of description, and embodiments are not limited thereto.

The gate capping pattern 145 may be disposed on the upper surfaces of the upper gate electrode and the gate spacer 140. The gate capping pattern 145 may cover the upper surface of the upper gate electrode. The gate capping pattern 145 may overlap with the upper gate electrode in the third direction D3. In some embodiments, a portion of a side surface of the gate capping pattern 145 may be in contact with the gate spacer 140. The upper surface of the gate capping pattern 145 may be disposed on the same plane as the upper surface of an interlayer insulating film 180. However, embodiments are not limited thereto. The side surface of the gate capping pattern 145 may be in contact with an etch stop film 185.

For example, the gate capping pattern 145 may include at least one of silicon nitride (SiN), silicon oxynitride (SiON), silicon carbonitride (SiCN), silicon oxycarbonitride (SiOCN), or a combination thereof. The gate capping pattern 145 may include a material having etch selectivity with respect to the interlayer insulating film 180.

The first source/drain pattern 150 may be disposed in the active region AP. The first source/drain pattern 150 may be disposed on the lower insulating layer 110. The first source/drain pattern 150 may be disposed on at least one side of the gate electrode 120. The first source/drain pattern 150 may be disposed on a first side surface of the channel pattern CP. The first source/drain pattern 150 may be connected to the channel pattern CP. A portion of the side surface of the first source/drain pattern 150 may be in contact with the plurality of sheet patterns NS. Another portion of the side surface of the first source/drain pattern 150 may be in contact with the gate insulating film 130.

The first source/drain pattern 150 may include a first liner film 152, a first lower filling film 154, a first middle filling film 156, and a first upper filling film 158. For example, the first liner film 152, the first lower filling film 154, the first middle filling film 156, and the first upper filling film 158 may be a first liner region (or a first liner) 152, a first lower region 154, a first middle region 156, and a first upper region 158, respectively. The first lower filling film 154, the first middle filling film 156, and the first upper filling film 158 may be surrounded by the first liner film 152.

The first liner film 152 may define a sidewall of the first source/drain pattern 150. The first liner film 152 may extend along the side surfaces of the plurality of sheet patterns NS. The first liner film 152 may be in contact with the side surfaces of the plurality of sheet patterns NS and the gate insulating film 130. The gate insulating film 130 may be disposed between the first liner film 152 and the gate electrode 120. In some embodiments, the first liner film 152 may be conformally formed.

The first lower filling film 154, the first middle filling film 156, and the first upper filling film 158 may be disposed in the first liner film 152. For example, in terms of cross-sectional area (in a cross-sectional view), the first lower filling film 154, the first middle filling film 156, and the first upper filling film 158 may be disposed between the first liner films 152. The first lower filling film 154 may be disposed on the connection structure 320. The first middle filling film 156 may be disposed on the first lower filling film 154. The first upper filling film 158 may be disposed on the first middle filling film 156. The first lower filling film 154, the first middle filling film 156, and the first upper filling film 158 may be sequentially stacked on the connection structure 320.

The second source/drain pattern 250 may be disposed in the active region AP. The second source/drain pattern 250 may be disposed on the lower insulating layer 110. The second source/drain pattern 250 may be disposed on at least one side of the gate electrode 120. The second source/drain pattern 250 may be disposed on a second side surface of the channel pattern CP. The second source/drain pattern 250 may be connected to the channel pattern CP. A portion of the side surface of the second source/drain pattern 250 may be in contact with the plurality of sheet patterns NS. Another portion of the side surface of the second source/drain pattern 250 may be in contact with the gate insulating film 130.

The first source/drain pattern 150 may be disposed to be spaced apart from the second source/drain pattern 250. For example, the first source/drain pattern 150 may be disposed to be spaced apart from the second source/drain pattern 250 in the first direction D1. However, embodiments are not limited thereto. For example, the first source/drain pattern 150 and the second source/drain pattern 250 may be disposed to be spaced apart from each other in the second direction D2. For example, the first source/drain pattern 150 and the second source/drain pattern 250 may be disposed in different active regions AP.

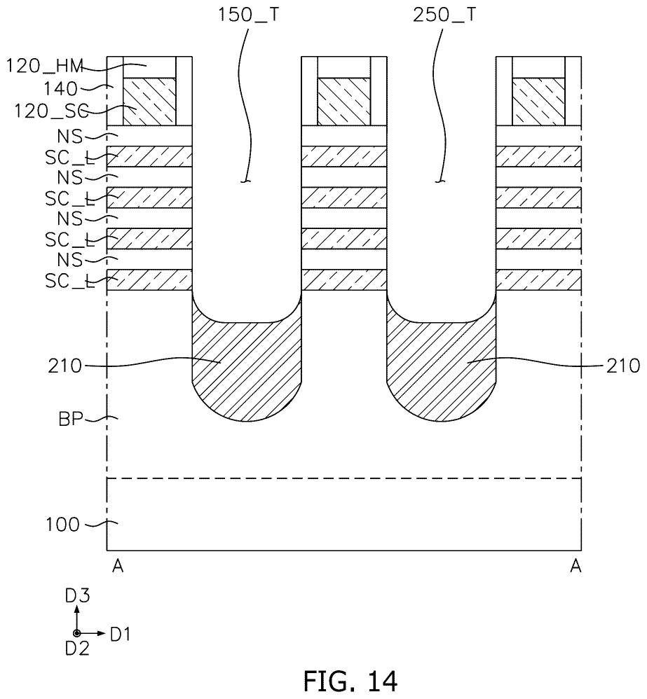

The second source/drain pattern 250 may be disposed in a source/drain trench 250_T. The source/drain trench 250_T may extend in the third direction D3. The semiconductor pattern 210 may be disposed on a bottom surface of the source/drain trench 250_T. The second source/drain pattern 250 may fill the remaining source/drain trench 250_T after the semiconductor pattern 210 is formed. The second source/drain pattern 250 may be disposed on the semiconductor pattern 210 (as described later with reference to FIGS. 14 to 18). The bottom surface of the source/drain trench 250_T may have a rounded-shape. For example, the bottom surface of the source/drain trench 250_T may be curved thereby convexly protruding toward the lower wiring 300.

The second source/drain pattern 250 may include a second liner film 252, a second lower filling film 254, a second middle filling film 256, and a second upper filling film 258. For example, the second liner film 252, the second lower filling film 254, the second middle filling film 256, and the second upper filling film 258 may be a second liner region (or second liner) 252, a second lower region 254, a second middle region 256, and a second upper region 258, respectively. The second lower filling film 254, the second middle filling film 256, and the second upper filling film 258 may be surrounded by the second liner film 252.

The second liner film 252 may define a sidewall of the second source/drain pattern 250. The second liner film 252 may extend along a side surface of the source/drain trench 250 T and an upper surface of the semiconductor pattern 210. The second liner film 252 may extend along the side surfaces of the plurality of sheet patterns NS. The second liner film 252 may be in contact with the side surfaces of the plurality of sheet patterns NS and the gate insulating film 130. The gate insulating film 130 may be disposed between the second liner film 252 and the gate electrode 120. In some embodiments, the second liner film 252 may be conformally formed.

The second lower filling film 254, the second middle filling film 256, and the second upper filling film 258 may be disposed in the second liner film 252. For example, in terms of cross-sectional area, the second lower filling film 254, the second middle filling film 256, and the second upper filling film 258 may be disposed between the second liner films 252. The second lower filling film 254 may be disposed on the second liner film 252. The second middle filling film 256 may be disposed on the second lower filling film 254. The second upper filling film 258 may be disposed on the second middle filling film 256. The second lower filling film 254, the second middle filling film 256, and the second upper filling film 258 may be sequentially stacked in (or on) the second liner film 252.

Each of the first source/drain pattern 150 and the second source/drain pattern 250 may be an epitaxial pattern formed by a selective epitaxial growth process using the channel pattern CP as a seed. Each of the first source/drain pattern 150 and the second source/drain pattern 250 may serve as a source/drain of a transistor that uses the sheet pattern NS as a channel region.

Each of the first source/drain pattern 150 and the second source/drain pattern 250 may include a semiconductor material. For example, each of the first source/drain pattern 150 and the second source/drain pattern 250 may include an element semiconductor material such as silicon (Si) or germanium (Ge). In addition, for example, each of the first source/drain pattern 150 and the second source/drain pattern 250 may include a binary compound, a ternary compound including at least two or more of carbon (C), silicon (Si), germanium (Ge), or tin (Sn), or a compound of these doped with a group IV element. For example, each of the first source/drain pattern 150 and the second source/drain pattern 250 may include silicon (Si), silicon-germanium (SiGe), germanium (Ge), silicon carbide (SiC), etc., but is not limited thereto.

Each of the first source/drain pattern 150 and the second source/drain pattern 250 may include a dopant, which may be charge carrier impurities or charge carrier dopants) doped into a semiconductor material. The doped dopant may include at least one of boron (B), aluminum (Al), gallium (Ga), indium (In), phosphorus (P), carbon (C), arsenic (As), antimony (Sb), bismuth (Bi), or oxygen (O), but is not limited thereto. The concentrations of dopants doped in the first source/drain pattern 150 and the second source/drain pattern 250 will be described in detail.

A concentration of a dopant in the first liner film 152 may be less than a concentration of a dopant in each of the first lower filling film 154, the first middle filling film 156, and the first upper filling film 158. In some embodiments, the first liner film 152 may not include a dopant. For example, the first liner film 152 may have a net concentration of p-type and n-type dopants that is close to zero, or lower than a level considered to be undoped, or lower than the intrinsic level of carrier concentration. The concentration of the dopant in the first lower filling film 154 may be greater than the concentration of the dopant in the first middle filling film 156. The concentration of the dopant in the first upper filling film 158 may be greater than the concentration of the dopant in the first middle filling film 156.

In semiconductor technology, if a semiconductor contains both p-type and n-type impurities, the conductivity-type of the semiconductor will be determined by which type of impurity is in greater concentration. Therefore, if a semiconductor has both p-type and n-type impurities, the net conductivity type will be determined by the dominant impurity concentration. As used herein, a “concentration of (a) dopant(s)” or a “dopant concentration” in a semiconductor region refers to the net concentration of the dominant impurities in the semiconductor region (e.g., the absolute value of the difference between the number (or amount) of p-type impurities and the number (or amount) of n-type impurities per unit volume of the semiconductor region, with the larger quantity being subtracted by the smaller one). For example, the “concentration of (a) dopant(s)” or “dopant concentration” in a semiconductor region may refer to either the average concentration or the maximum concentration in the semiconductor region.

The concentration of the dopant in the second liner film 252 may be less than the concentration of the dopant in each of the second lower filling film 254, the second middle filling film 256, and the second upper filling film 258. In some embodiments, the second liner film 252 may not include a dopant. The concentration of the dopant in the second lower filling film 254 may be greater than the concentration of the dopant in the second middle filling film 256. The concentration of the dopant in the second upper filling film 258 may be greater than the concentration of the dopant in the second middle filling film 256.

The concentration of the dopant in the first lower filling film 154 may be the same as the concentration of the dopant in the second lower filling film 254. In some embodiments, the first lower filling film 154 and the second lower filling film 254 may be formed by the same process. One end of the connection structure 320 may be disposed on the first lower filling film 154. One end of the lower source/drain contact 322 may be in contact with the first lower filling film 154. An upper region of the lower source/drain contact 322 may have a shape that is convexly inserted into the first lower filling film 154. In order to improve the electrical characteristics of semiconductor devices, it is desirable to lower the contact resistance between the source/drain contact and the source/drain pattern. In the semiconductor device according to some embodiments, since the concentration of the dopant in the first lower filling film 154 is greater than the concentration of the dopant in the first middle filling film 156, the contact resistance between the lower source/drain contact 322 and the first lower filling film 154 may be reduced. As a result, the electrical characteristics of the semiconductor device may be improved and reliability may be improved.

The concentration of the dopant in the first middle filling film 156 may be the same as the concentration of the dopant in the second middle filling film 256. In some embodiments, the first middle filling film 156 and the second middle filling film 256 may be formed by the same process. The concentration of the dopant in the first upper filling film 158 may be the same as the concentration of the dopant in the second upper filling film 258. In some embodiments, the first upper filling film 158 and the second upper filling film 258 may be formed by the same process.

As discussed above, the term “same” is intended to encompass nearly identical features. For example, when a first concentration is the same as a second concentration, the two concentrations may be within a small range which is a tolerance acceptable with respect to the manufacturing process of the semiconductor device.

The active region AP may be a region in which a PMOS transistor (P-Channel Metal-Oxide-Semiconductor Transistor) is formed. In another aspect, the active region AP may be a region in which an NMOS transistor (N-Channel Metal-Oxide-Semiconductor Transistor) is formed. If the active region AP is a region where the PMOS transistor is formed, the first liner film 152, the first lower filling film 154, the first middle filling film 156, and the first upper filling film 158 may include silicon (Si) and germanium (Ge). A concentration of germanium in the first liner film 152 may be less than a concentration of germanium in each of the first lower filling film 154, the first middle filling film 156, and the first upper filling film 158. The concentration of germanium in the first middle filling film 156 may be less than the concentration of germanium in the first lower filling film 154. The concentration of germanium in the first upper filling film 158 may be greater than the concentration of germanium in the first middle filling film 156.

The description of the concentrations of germanium in the first liner film 152, the first lower filling film 154, the first middle filling film 156, and the first upper filling film 158 may be the same as the description of the concentrations of germanium in the second liner film 252, the second lower filling film 254, the second middle filling film 256, and the second upper filling film 258. For example, the description on the impurities in the first source/drain pattern 150 may also be applied to the second source/drain pattern 250.

The semiconductor pattern 210 may be disposed in the source/drain trench 250 T. The semiconductor pattern 210 may be disposed below the second source/drain pattern 250. The semiconductor pattern 210 may be disposed below the second liner film 252. The semiconductor pattern 210 may fill the source/drain trench 250 T between the second liner film 252 and the lower insulating layer 110. The semiconductor pattern 210 may be disposed in the lower insulating layer 110. For example, the semiconductor pattern 210 may overlap with the lower insulating layer 110 in the first direction D1. The semiconductor pattern 210 may include a material having etch selectivity with respect to the lower insulating layer 110. For example, the semiconductor pattern 210 may include silicon (Si) and germanium (Ge). The concentration of germanium (Ge) included in the semiconductor pattern 210 may be greater than the concentration of germanium (Ge) included in the second lower filling film 254. However, embodiments are not limited thereto.

The connection structure 320 may be disposed in the lower insulating layer 110. The connection structure 320 may be formed through the lower insulating layer 110. The connection structure 320 may connect the lower wiring 300 and the first source/drain pattern 150. One end of the connection structure 320 may be disposed on a lower surface of the first lower filling film 154, and the other end of the connection structure 320 may be disposed on the upper surface 300_US of the lower wiring 300.

The connection structure 320 may be a connection pattern including the lower source/drain contact 322 and a lower via 324. The lower via 324 may be disposed on the upper surface 300_US of the lower wiring 300. The lower source/drain contact 322 may be disposed on the lower via 324. The lower source/drain contact 322 and a lower via 324 may be a continuous structure formed of the same material without a boundary interface therebetween.

In some embodiments, a first distance H1 from the upper surface 300_US of the lower wiring 300 to an upper surface of the lower via 324 may be greater than a second distance H2 from the upper surface 300_US of the lower wiring 300 to a lowermost end of the semiconductor pattern 210. The upper surface of the lower via 324 may refer to a stepped surface between the lower via 324 and the lower source/drain contact 322. The first distance H1 and the second distance H2 may refer to a distance in the third direction D3. The second distance H2 may be a shortest distance in the direction D3 between the upper surface 300_US of the lower wiring 300 and a lowermost end (or lowermost portion) of the source/drain trench 250_T.

The lowermost end of the source/drain trench 250_T may be located at a central portion of the bottom surface of the source/drain trench 250_T. The second source/drain pattern 250 may be disposed in the source/drain trench 250_T. The first middle filling film 156 may be located at a higher height level than the first lower filling film 154. The second middle filling film 256 may be located at a higher height level than the second lower filling film 254. The first and second lower filling films 154 and 254 may be located at higher height levels than the bottom surface of the source/drain trench 250_T.

The stepped surface may be disposed between the lower via 324 and the lower source/drain contact 322. The lower via 324 and the lower source/drain contact 322 may be divided by the stepped surface. For example, The stepped surface may extend in the first and second directions D1 and D2. The lower via 324 and the lower source/drain contact 322 may be distinguished by a virtual horizontal plane extending along the stepped surface. The lower source/drain contact 322 may be electrically connected to the first source/drain pattern 150. The lower source/drain contact 322 may be disposed on lower surfaces of the first liner film 152 and the first lower filling film 154. The connection structure 320 may further include a first silicide film 160 may be disposed between the lower source/drain contact 322 and the first liner film 152, and between the lower source/drain contact 322 and the first lower filling film 154.

The lower wiring 300 may be disposed below the lower insulating layer 110. The lower wiring 300 may extend in the first direction D1. The lower wiring 300 may be connected to the connection structure 320. The connection structure 320 may electrically connect the lower wiring 300 to the first source/drain pattern 150. The lower wiring 300 may be one of a power rail to supply power or a ground rail that is grounded. For example, the lower wiring 300 may serve as either a power rail, supplying power, or a ground rail. For example, power (e.g., VDD) may be a voltage used for powering the circuit so that all components of the semiconductor device function correctly, and may be a positive voltage that is supplied to the drain terminal of a transistor. Ground (e.g., VSS) may be set to 0V. VSS may serve as the reference voltage and may be connected to the source terminal of a transistor.

For example, the lower wiring (or lower wiring pattern) 300 may be a conductive pattern including at least one of molybdenum (Mo), copper (Cu), carbon (C), silver (Ag), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), magnesium (Mg), aluminum (Al), zirconium (Zr), tungsten (W), ruthenium (Ru), iridium (Ir), and rhodium (Rh). However, embodiments are not limited thereto.

The etch stop film 185 may be disposed on an upper surface of the first source/drain pattern 150 and an upper surface of the second source/drain pattern 250. The etch stop film 185 may extend along side surfaces of the gate spacer 140 and the gate capping pattern 145. The etch stop film 185 may include a material having etch selectivity with respect to the interlayer insulating film 180. For example, the etch stop film 185 may include at least one of silicon nitride (SiN), silicon oxide (SiO), silicon oxynitride (SiON), silicon oxycarbonitride (SiOCN), silicon boron nitride (SiBN), silicon oxide boron nitride (SiOBN), silicon oxycarbide (SiOC), or a combination thereof.

The interlayer insulating film 180 may be disposed on the etch stop film 185. The interlayer insulating film 180 may be disposed on the first source/drain pattern 150 and the second source/drain pattern 250. The interlayer insulating film 180 may be disposed on one side of the upper gate electrode. The interlayer insulating film 180 may be disposed between the upper gate electrodes.

For example, the interlayer insulating film 180 may include at least one of silicon oxide (SiO), silicon nitride (SiN), silicon oxynitride (SiON), or a low-k material. For example, the low dielectric constant material may include fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutoxysiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or a combination thereof, but is not limited thereto.

The upper source/drain contact 272 may be formed through the interlayer insulating film 180 and the etch stop film 185 to be connected to the second source/drain pattern 250. The upper source/drain contact 272 may be formed through an upper surface of the second upper filling film 258. One end of the upper source/drain contact 272 may be disposed in the second upper filling film 258. The upper source/drain contact 272 may be electrically connected to the second upper filling film 258. A second silicide film 260 may be disposed between the second upper filling film 258 and the upper source/drain contact 272. The upper source/drain contact 272 may be in contact with the second silicide film 260.

The upper via 274 may be disposed in a first upper insulating layer 392. The upper via 274 may be formed through the first upper insulating layer 392. The first upper insulating layer 392 may be disposed on the upper surface of the gate capping pattern 145 and the upper surface of the interlayer insulating film 180. The upper via 274 may be disposed on the upper source/drain contact 272. The upper via 274 may be electrically connected to the upper source/drain contact 272. In some embodiments, an interlayer etch stop film may be disposed between the first upper insulating layer 392 and the gate capping pattern 145 and between the first upper insulating layer 392 and the interlayer insulating film 180.

A second upper insulating layer 394 may be disposed on the first upper insulating layer 392. An upper wiring (or an upper wiring pattern) 380 may be disposed in the second upper insulating layer 394. The upper wiring 380 may be disposed on the upper via 274. The upper wiring 380 may be electrically connected to the upper via 274. The upper wiring 380 may extend in the second direction D2. However, embodiments are not limited thereto. For example, the upper wiring 380 may extend in the first direction D1.

The description of the material of the first upper insulating layer 392 and the second upper insulating layer 394 may be the same as the description of the material of the lower insulating layer 110.

Each of the upper source/drain contact 272 and the connection structure 320 may be a conductive pattern and include a conductive material. For example, each of the upper source/drain contact 272 and the connection structure 320 may include at least one of ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), a two-dimensional material (2D material), aluminum (Al), copper (Cu), silver (Ag), gold (Au), manganese (Mn), or molybdenum (Mo).

The upper via 274 may include a conductive material. For example, the upper via 274 may include at least one of molybdenum (Mo), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), 2D material, aluminum (Al), copper (Cu), silver (Ag), gold (Au), or manganese (Mn).

FIG. 3 is a diagram provided to explain a semiconductor device according to some embodiments. For convenience of description, different configurations from those described in FIGS. 1 and 2 will be mainly described. Throughout the specification, like features and elements have been identified by the same or similar reference numerals and/or letters.

Referring to FIG. 3, in a semiconductor device according to some embodiments, a width of the first source/drain pattern 150 in the first direction D1 and a width of the second source/drain pattern 250 in the first direction D1 may not be constant.

A side surface 150_SW of the first source/drain pattern 150 may include a flat surface and/or a curved surface. For example, the side surface 150_SW of the first source/drain pattern 150 may have a wavy shape. A portion of the side surface 150_SW of the first source/drain pattern 150 that overlaps with the gate electrode 120 in the first direction D1 may have a shape protruding toward the gate electrode 120. Although the contact surface (or boundary) between the side surface 150_SW of the first source/drain pattern 150 and the plurality of sheet patterns NS is illustrated as a flat surface, embodiments are not limited thereto. For example, the contact surface between the side surface 150_SW of the first source/drain pattern 150 and the plurality of sheet patterns NS may include a curved surface protruding toward the first source/drain pattern 150.

The first liner film 152 may define the side surface 150_SW of the first source/drain pattern 150. The first liner film 152 may extend along the side surface 150_SW of the first source/drain pattern 150 and may have a wavy shape. In some embodiments, the first liner film 152 may be conformally formed.

A side surface 250_SW of the second source/drain pattern 250 may include a flat surface and/or a curved surface. For example, the side surface 250_SW of the second source/drain pattern 250 may have a wavy shape. A portion of the side surface 250_SW of the second source/drain pattern 250 that overlaps with the gate electrode 120 in the first direction D1 may have a shape protruding toward the gate electrode 120. Although the contact surface between the side surface 250 SW of the second source/drain pattern 250 and the plurality of sheet patterns NS is illustrated as a flat surface, embodiments are not limited thereto. For example, the contact surface between the side surface 250_SW of the second source/drain pattern 250 and the plurality of sheet patterns NS may include a curved surface protruding toward the second source/drain pattern 250.

The second liner film 252 may define the side surface 250_SW of the second source/drain pattern 250. The second liner film 252 may extend along the side surface 250_SW of the second source/drain pattern 250 and may have a wavy shape. In some embodiments, the second liner film 252 may be conformally formed.

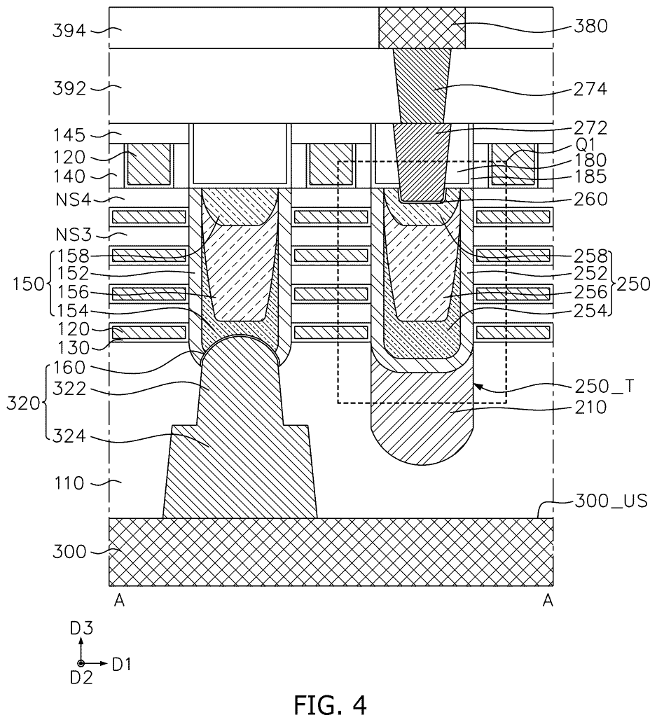

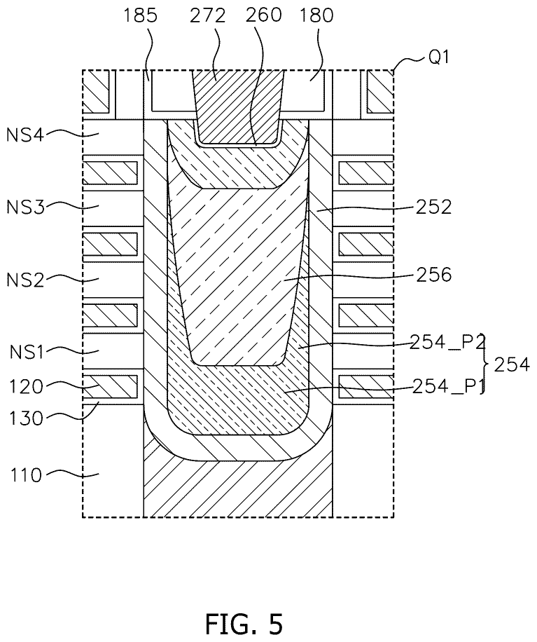

FIG. 4 is a diagram provided to explain a semiconductor device according to some embodiments. FIG. 5 is an enlarged view provided to explain a region Q1 of FIG. 4. For convenience of description, different configurations from those described in FIGS. 1 and 2 will be mainly described.

Referring to FIGS. 4 and 5, in a semiconductor device according to some embodiments, the second lower filling film 254 may include a first portion 254_P1 and a second portion 254_P2.

The channel pattern CP may include first to fourth sheet patterns NS1, NS2, NS3, and NS4. The first to fourth sheet patterns NS1, NS2, NS3, and NS4 may be disposed to be spaced apart from each other in the third direction D3. The first to fourth sheet patterns NS1, NS2, NS3, and NS4 may be sequentially stacked on the lower insulating layer 110.

The second lower filling film 254 may include the first portion 254_P1 and the second portion 254_P2 protruding from the first portion 254_P1 in the third direction D3. The first portion 254_P1 of the second lower filling film 254 may be disposed on a bottom surface of the second liner film 252.

At least a portion of the second lower filling film 254 may be disposed on the side surface of the channel pattern CP. For example, the second portion 254_P2 of the second lower filling film 254 may be disposed on the side surface of the channel pattern CP. Specifically, the second portion 254_P2 of the second lower filling film 254 may be disposed on the side surfaces of the first sheet pattern NS1, the second sheet pattern NS2, and the third sheet pattern NS3. For example, the second portion 254_P2 of the second lower filling film 254 may overlap with the first sheet pattern NS1, the second sheet pattern NS2, and the third sheet pattern NS3 with respect to a side view in the first direction D1.

The first lower filling film 154 may include a protruding portion. The description of the protruding portion of the first lower filling film 154 may be the same as the description of the second portion 254_P2 of the second lower filling film 254. For example, a portion of the first lower filling film 154 may overlap with the first sheet pattern NS1, the second sheet pattern NS2, and the third sheet pattern NS3 with respect to a side view in the first direction D1.

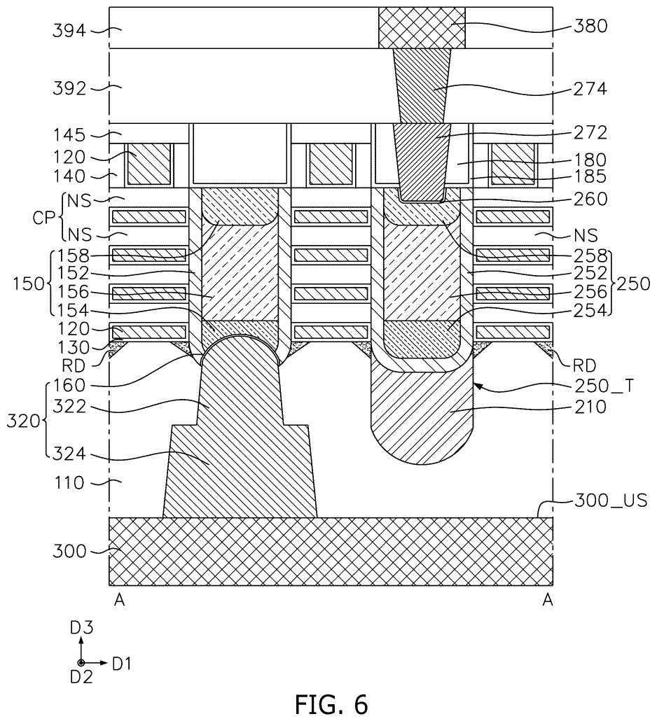

FIG. 6 is a diagram provided to explain a semiconductor device according to some embodiments. For convenience of description, different configurations from those described in FIGS. 1 and 2 will be mainly described.

Referring to FIG. 6, the semiconductor device according to some embodiments may further include a residual pattern RD.

The residual pattern RD may be disposed between the lower insulating layer 110 and the gate electrode 120. The residual pattern RD may be in contact with the lower insulating layer 110. In some embodiments, the residual pattern RD may be disposed on an upper sidewall of the semiconductor pattern 210. The residual pattern RD may be disposed on an upper sidewall of the connection structure 320. The residual pattern RD may be a residue left when the semiconductor substrate is removed. The residual pattern RD may include silicon or silicon germanium (SiGe). For example, the residual pattern RD may be a semiconductor pattern surrounding each of the trenches in which the first source/drain pattern 150 and the second source/drain pattern 250 are disposed.

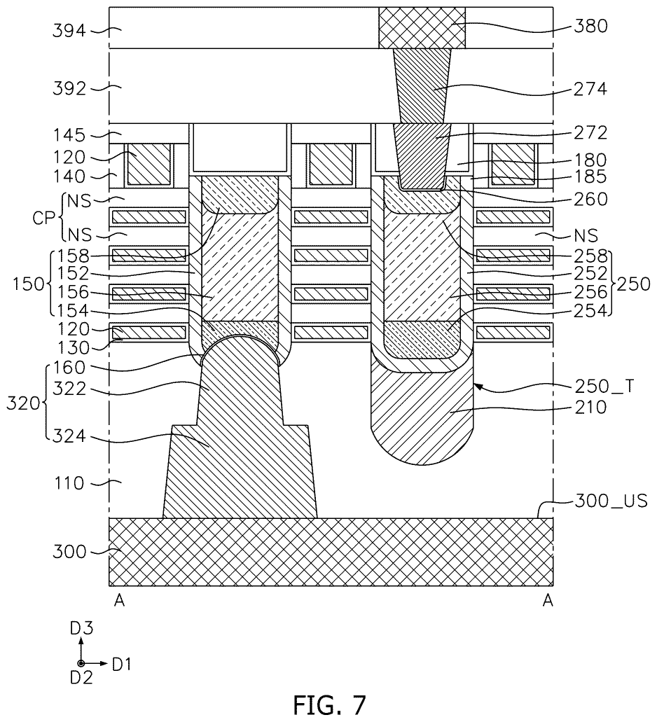

FIG. 7 is a diagram provided to explain a semiconductor device according to some embodiments. For convenience of description, different configurations from those described in FIGS. 1 and 2 will be mainly described.

Referring to FIG. 7, in the semiconductor device according to some embodiments, the upper surface of the first source/drain pattern 150 may be disposed on a different plane from the upper surface of the channel pattern CP. The upper surface of the second source/drain pattern 250 may be disposed on a different plane from the upper surface of the channel pattern CP. The upper surface of the first liner film 152 and the upper surface of the first upper filling film 158 may define the upper surface of the first source/drain pattern 150. The upper surface of the second liner film 252 and the upper surface of the second upper filling film 258 may define the upper surface of the second source/drain pattern 250.

For example, the upper surface of the first source/drain pattern 150 and/or the upper surface of the second source/drain pattern 250 may be disposed at a higher level than the upper surface of the channel pattern CP. The upper surface of the channel pattern CP may be an upper surface of the sheet pattern NS disposed at an uppermost position among the plurality of sheet patterns NS. The uppermost position of the first source/drain pattern 150 may overlap with the gate spacer 140 in the first direction D1. The uppermost position of the second source/drain pattern 250 may overlap with the gate spacer 140 in the first direction D1.

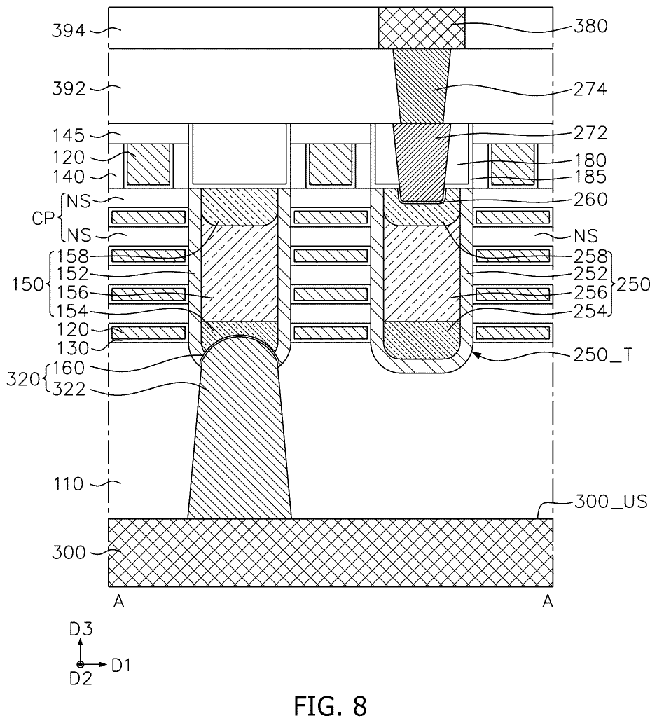

FIG. 8 is a diagram provided to explain a semiconductor device according to some embodiments. For convenience of description, different configurations from those described in FIGS. 1 and 2 will be mainly described.

Referring to FIG. 8, unlike FIG. 2, the semiconductor device according to some embodiments may not include the semiconductor pattern 210.

The source/drain trench 250_T may be disposed on the lower insulating layer 110. The second source/drain pattern 250 may be disposed in the source/drain trench 250_T. The second liner film 252 may extend along the side surface and the bottom surface of the source/drain trench 250_T.

The lower source/drain contact 322 may be disposed in the lower insulating layer 110. The lower source/drain contact 322 may be disposed between the lower wiring 300 and the first source/drain pattern 150. One end of the lower source/drain contact 322 may be disposed on the first lower filling film 154 of the first source/drain pattern 150. The other end of the lower source/drain contact 322 may be disposed on the upper surface 300_US of the lower wiring 300. Unlike FIG. 2, the lower wiring 300 and the first source/drain pattern 150 may be electrically connected to each other solely through the lower source/drain contact 322. For example, the connection structure may include the lower source/drain contact 322 and the first silicide film 160. The connection structure may be in contact with the first lower filling film 154. The lower wiring 300 and the first source/drain pattern 150 may be electrically connected to each other.

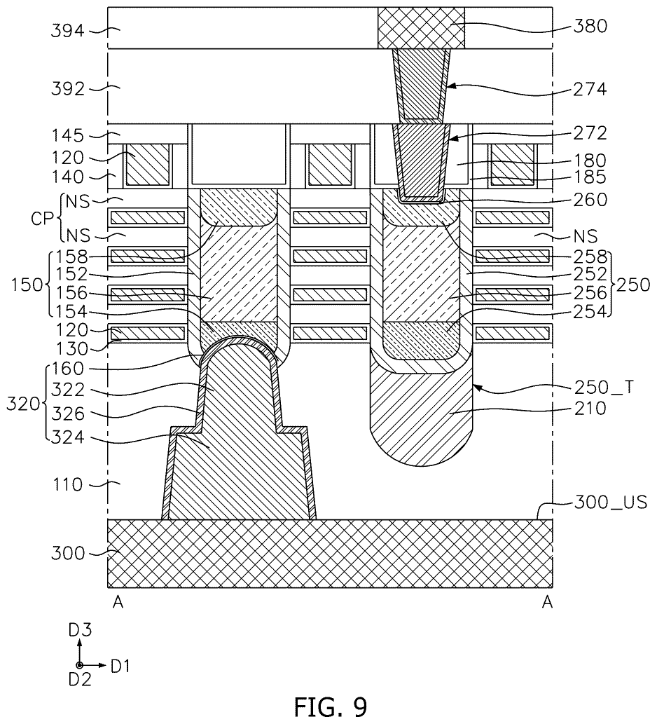

FIG. 9 is a diagram provided to explain a semiconductor device according to some embodiments. For convenience of description, different configurations from those described in FIGS. 1 and 2 will be mainly described.

Referring to FIG. 9, in semiconductor devices according to some embodiments, the connection structure 320 may include a barrier film 326, the lower source/drain contact 322, and the lower via 324.

The barrier film 326 may define a side surface and an upper surface of the connection structure 320. The barrier film 326 may be in contact with the first silicide film 160 and the lower insulating layer 110. The lower source/drain contact 322 and the lower via 324 may be disposed in the barrier film 326. The barrier film 326 may not be disposed between the lower via 324 and the lower wiring 300. A boundary surface between the lower source/drain contact 322 and the lower via 324 may not be distinguished from each other. In some embodiments, the lower source/drain contact 322 and the lower via 324 may be formed by the same process.

For example, the barrier film 326 may be electrically conductive and include at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), or a 2D material.

In some embodiments, each of the upper source/drain contact 272 and the upper via 274 may include a barrier film and a filling film such that the barrier film surrounds the filling film and the filling film is formed within the barrier film, as described in the drawing. The description of materials of the barrier film of the upper source/drain contact 272 and the barrier film of the upper via 274 may be the same as that of the barrier film 326 of the connection structure 320. For example, the material of the filing film of each of the upper source/drain contact 272 and the upper via 274 may be the same as that of the upper source/drain contact 272 and the upper via 274 described with reference to FIGS. 1 and 2.

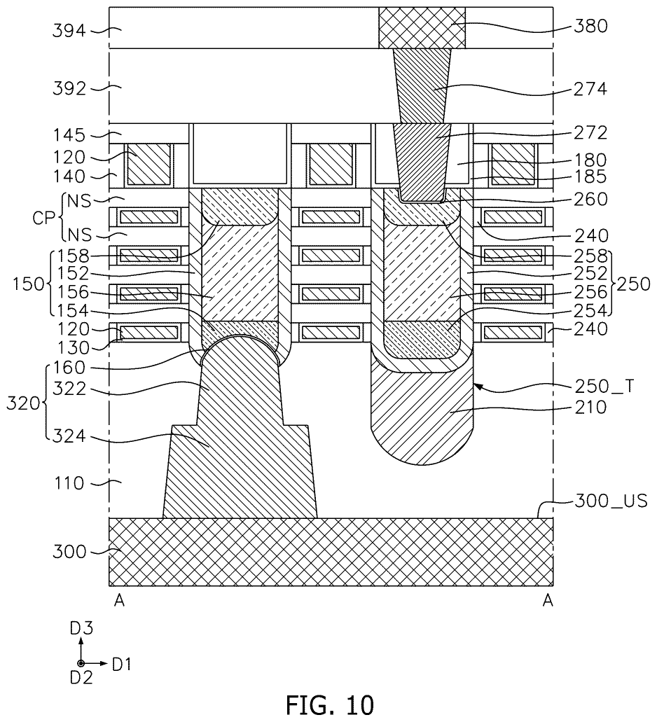

FIG. 10 is a diagram provided to explain a semiconductor device according to some embodiments. For convenience of description, different configurations from those described in FIGS. 1 and 2 will be mainly described.

Referring to FIG. 10, the semiconductor device according to some embodiments may further include an inner gate spacer 240.

The inner gate spacer 240 may be disposed between the gate electrode 120 and the first source/drain pattern 150, and between the gate electrode 120 and the second source/drain pattern 250. The inner gate spacer 240 may be disposed on the first liner film 152 and the second liner film 252. The gate electrode 120 may be spaced apart from the first source/drain pattern 150 and the second source/drain pattern 250 by the inner gate spacer 240.

For example, the inner gate spacer 240 may include at least one of silicon oxide (SiO), silicon nitride oxide (SiON), silicon boron nitride (SiBN), silicon oxycarbonitride (SiOCN), and silicon nitride (SiN).

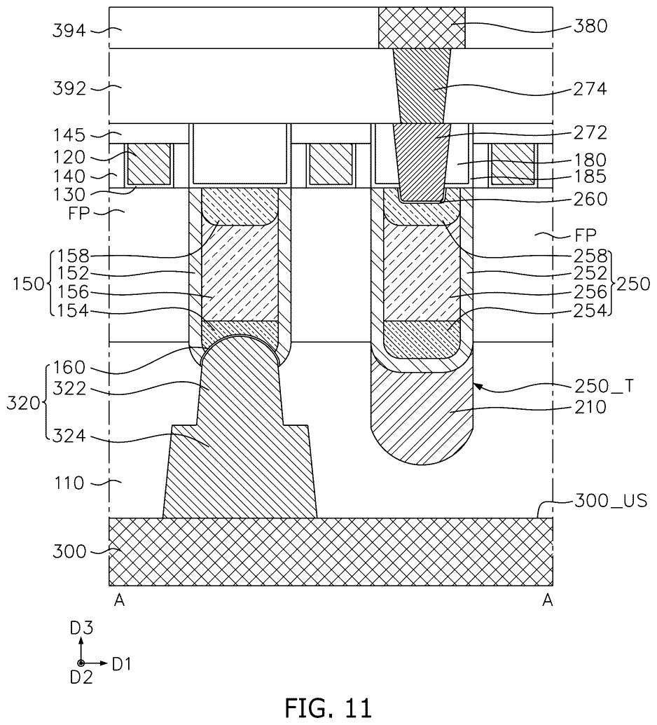

FIG. 11 is a diagram provided to explain a semiconductor device according to some embodiments. For convenience of description, different configurations from those described in FIGS. 1 and 2 will be mainly described.

Referring to FIG. 11, the semiconductor device according to some embodiments may include a fin-type transistor (FinFET) using a fin-shaped fin-type pattern FP as a channel region.

The fin-type pattern FP may protrude from the lower insulating layer 110 in the third direction D3. The fin-type pattern FP may be disposed in the active region extending in the first direction D1. The gate electrode 120 may surround three surfaces of the fin-type pattern FP in a cross-sectional view taken along a line, which is parallel to the second direction D2 and across the channel patterns CP. The first source/drain pattern 150 and the second source/drain pattern 250 may be disposed on a side surface of the fin-type pattern FP. The first source/drain pattern 150 and the second source/drain pattern 250 may be a source/drain region of a transistor that uses the fin-type pattern FP as a channel region.

The fin-type pattern FP may be a part of the silicon substrate, and may include an epitaxial layer grown from a substrate 100 (as shown in FIGS. 13 to 20). For example, the fin-type pattern FP may include an element semiconductor material such as silicon or germanium. In addition, the fin-type pattern FP may include a compound semiconductor, for example, a group IV-IV compound semiconductor or a group III-V compound semiconductor.

FIGS. 12 to 22 are diagrams illustrating intermediate stages, which are provided to explain a method for manufacturing a semiconductor device according to some embodiments. For reference, FIG. 12 is a cross-sectional view provided to explain a method for manufacturing a semiconductor device according to some embodiments, and FIGS. 13 to 22 are cross-sectional views taken along line A-A of FIG. 12. To enhance clarity in understanding the drawings, some components are omitted in FIG. 12.

Referring to FIGS. 12 and 13, a plurality of sacrificial semiconductor layers SC_L and the plurality of sheet patterns NS may be alternately stacked on the substrate 100, and a first source/drain trench 150 T and a second source/drain trench 250_T may be formed.

Specifically, a lower pattern BP may be formed on the substrate 100, and a plurality of sacrificial semiconductor layers SC_L and a plurality of active semiconductor layers may be alternately stacked on the lower pattern BP. The substrate 100 may be a bulk silicon or a silicon-on-insulator (SOI). For example, the substrate 100 may include silicon germanium (SiGe), silicon germanium on insulator (SGOI), indium antimony, lead tellurium compound, indium arsenide, indium phosphide, gallium arsenide, or gallium antimony, but is not limited thereto.

A gate sacrificial pattern 120_SC may be formed on the active semiconductor layer, and a hardmask pattern 120_HM and the gate spacer 140 may be formed on the gate sacrificial pattern 120_SC. An etching process may be performed using the hardmask pattern 120_HM and the gate spacer 140 as masks, and the first source/drain trench 150_T and the second source/drain trench 250_T may be formed. The first source/drain trench 150_T and the second source/drain trench 250_T may expose the lower pattern BP.

Referring to FIG. 14, the semiconductor pattern 210 may be formed in the first source/drain trench 150_T and the second source/drain trench 250_T. The semiconductor pattern 210 may be formed below the first source/drain trench 150_T and the second source/drain trench 250_T. The semiconductor pattern 210 may be formed in the lower pattern BP. For example, the semiconductor pattern 210 may overlap with the lower pattern BP in the first direction D1. The semiconductor pattern 210 may not be disposed on the sacrificial semiconductor layer SC_L. The semiconductor pattern 210 may not overlap with the sacrificial semiconductor layer SC_L in the first direction D1. The semiconductor pattern 210 may be an epitaxial pattern formed by a selective epitaxial growth process.

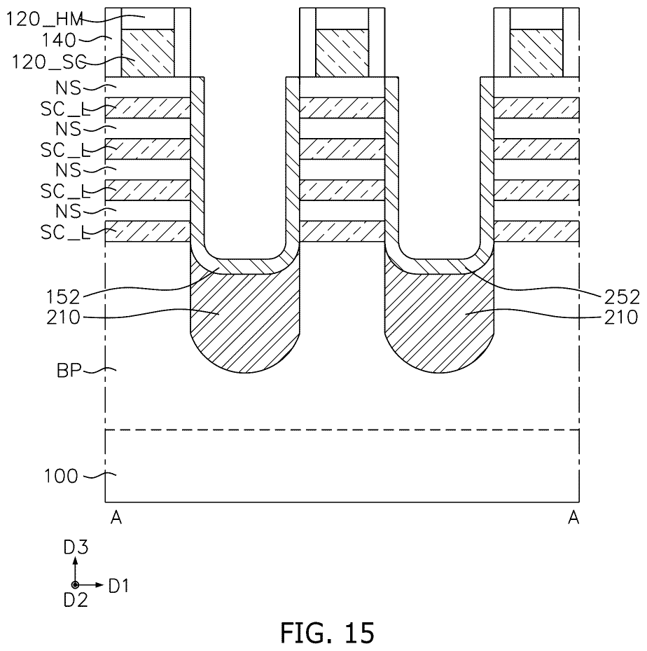

Referring to FIGS. 14 and 15, the first liner film 152 may be formed on the first source/drain trench 150_T, and the second liner film 252 may be formed on the second source/drain trench 250_T.

The first liner film 152 may be formed on a portion of the first source/drain trench 150 T that remains unfilled by the semiconductor pattern 210. The first liner film 152 may extend along a side surface of the first source/drain trench 150_T and the upper surface of the semiconductor pattern 210. The second liner film 252 may be formed on a portion of the second source/drain trench 250_T that remains unfilled by the semiconductor pattern 210. The second liner film 252 may extend along the side surface of the second source/drain trench 250_T and the upper surface of the semiconductor pattern 210.

Each of the first liner film 152 and the second liner film 252 may be an epitaxial pattern formed by a selective epitaxial growth process. The first liner film 152 and the second liner film 252 may be formed by the same process. In some embodiments, the first liner film 152 and the second liner film 252 may be conformally formed.

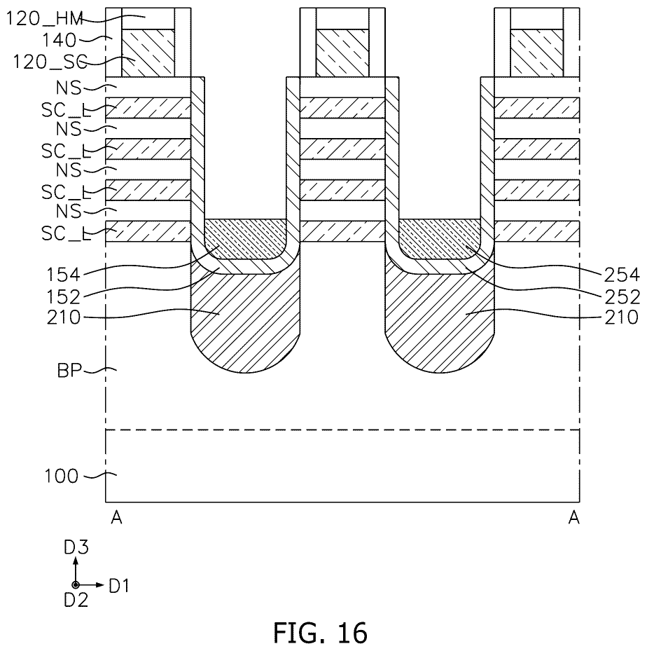

Referring to FIG. 16, the first lower filling film 154 may be formed on the first liner film 152, and the second lower filling film 254 may be formed on the second liner film 252. The first lower filling film 154 may be disposed in the first liner film 152. The first lower filling film 154 may be formed in a lower portion of the space within the first liner film 152. The second lower filling film 254 may be disposed in the second liner film 252. The second lower filling film 254 may be formed in a lower portion of the space within the second liner film 252.

Each of the first lower filling film 154 and the second lower filling film 254 may be an epitaxial pattern formed by a selective epitaxial growth process. Each of the first lower filling film 154 and the second lower filling film 254 may include a dopant. Each of the first lower filling film 154 and the second lower filling film 254 may be formed by the same process.

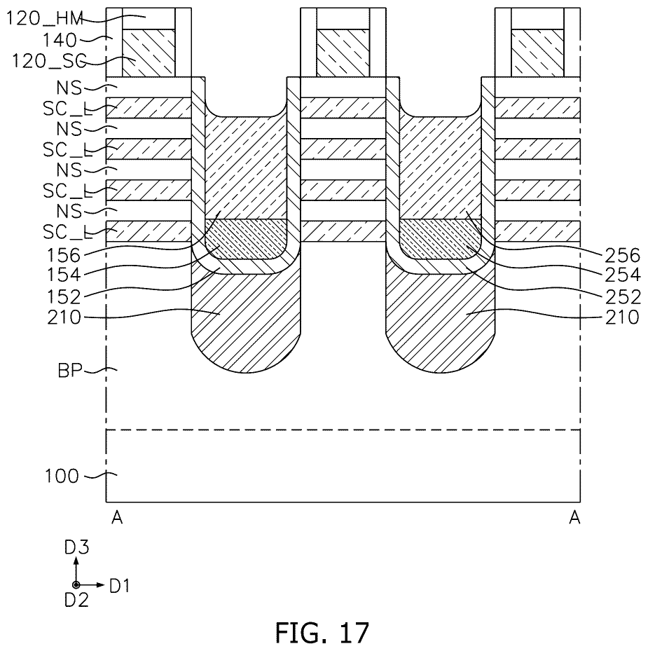

Referring to FIG. 17, the first middle filling film 156 may be formed on the first lower filling film 154, and the second middle filling film 256 may be formed on the second lower filling film 254. The first middle filling film 156 may be disposed in the first liner film 152. The first middle filling film 156 may be formed on an upper surface of the first lower filling film 154. The second middle filling film 256 may be disposed in the second liner film 252. The second middle filling film 256 may be formed on an upper surface of the second lower filling film 254.

Each of the first middle filling film 156 and the second middle filling film 256 may be an epitaxial pattern formed by a selective epitaxial growth process. Each of the first middle filling film 156 and the second middle filling film 256 may include a dopant. The concentration of the dopant in the first middle filling film 156 may be less than the concentration of the dopant in the first lower filling film 154, and the concentration of the dopant in the second middle filling film 256 may be less than the concentration of the dopant in the second lower filling film 254. Each of the first middle filling film 156 and the second middle filling film 256 may be formed by the same process.

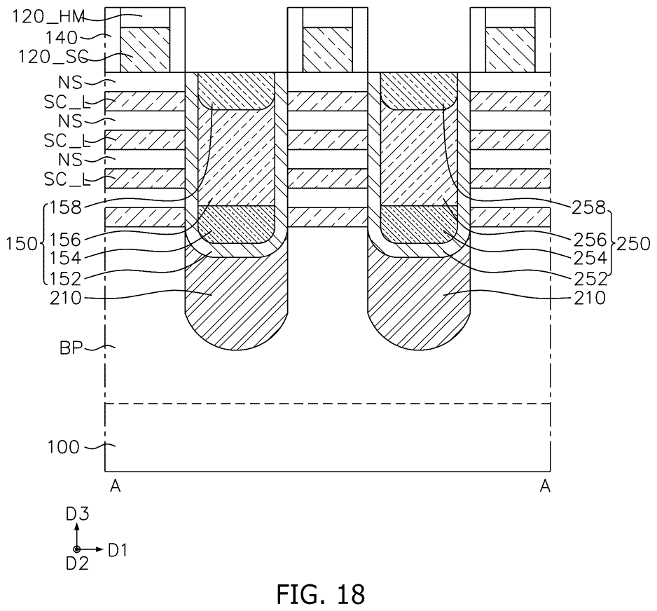

Referring to FIG. 18, the first upper filling film 158 may be formed on the first middle filling film 156, and the second upper filling film 258 may be formed on the second middle filling film 256. The first upper filling film 158 may be disposed in the first liner film 152. The first upper filling film 158 may be formed on an upper surface of the first middle filling film 156. The second upper filling film 258 may be disposed in the second liner film 252. The second upper filling film 258 may be formed on an upper surface of the second middle filling film 256.

Each of the first upper filling film 158 and the second upper filling film 258 may be an epitaxial pattern formed by a selective epitaxial growth process. Each of the first upper filling film 158 and the second upper filling film 258 may include a dopant. The concentration of the dopant in the first upper filling film 158 may be greater than the concentration of the dopant in the first middle filling film 156, and the concentration of the dopant in the second upper filling film 258 may be greater than the concentration of the dopant in the second middle filling film 256. Each of the first upper filling film 158 and the second upper filling film 258 may be formed by the same process.

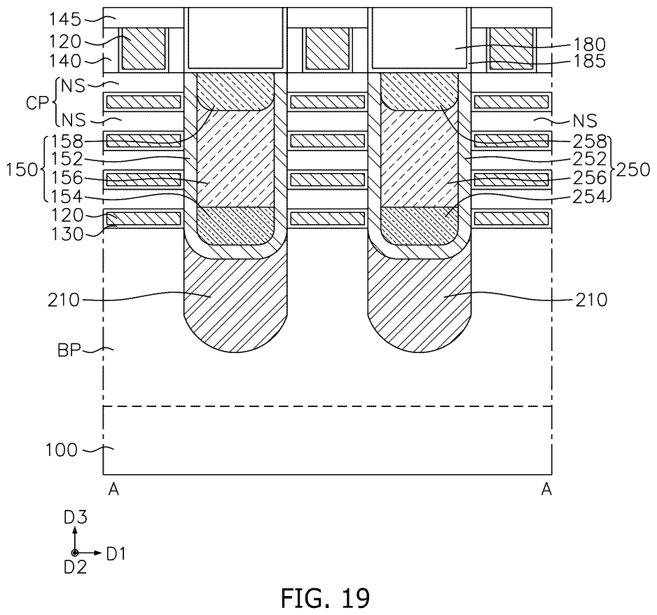

Referring to FIGS. 18 and 19, by a replacement process, the gate electrode 120 may be formed, and the gate capping pattern 145, the etch stop film 185, and the interlayer insulating film 180 may be formed.

Specifically, the hardmask pattern 120_HM, the gate sacrificial pattern 120_SC, and the sacrificial semiconductor layer SC_L may be removed and the plurality of sheet patterns NS may be exposed. The gate insulating film 130 and the gate electrode 120 may be sequentially formed on the plurality of sheet patterns NS. The gate capping pattern 145 may be formed, and the etch stop film 185 and the interlayer insulating film 180 may be formed.

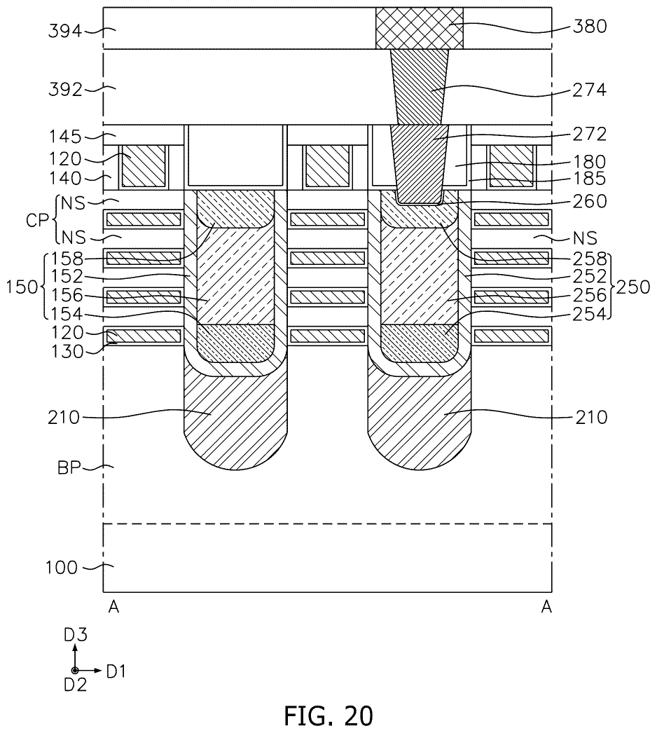

Referring to FIG. 20, the upper source/drain contact 272 may be formed on the second source/drain pattern 250. The first upper insulating layer 392 may be formed on the gate capping pattern 145 and the interlayer insulating film 180, and the upper via 274 may be formed on the upper source/drain contact 272. The second upper insulating layer 394 may be formed on the first upper insulating layer 392, and the upper wiring 380 may be formed on the upper via 274.

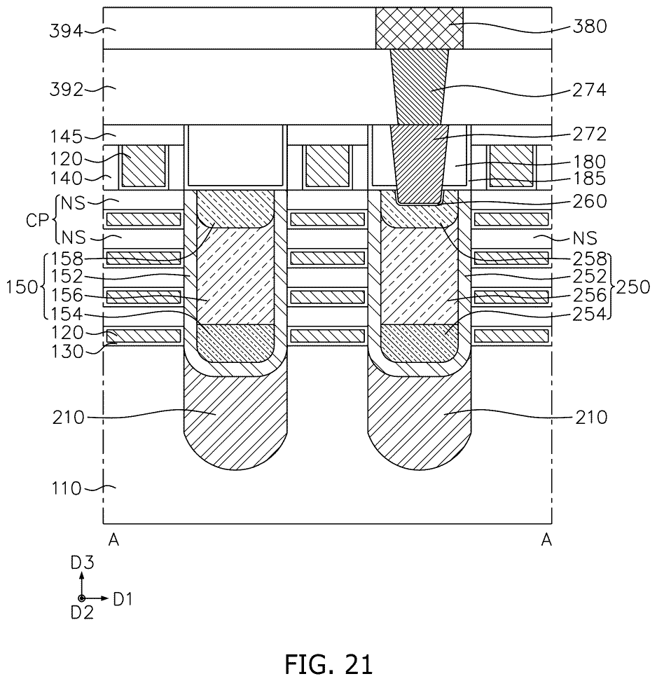

Referring to FIGS. 20 and 21, the substrate 100 and the lower pattern BP may be removed, and the lower insulating layer 110 may be formed. The lower insulating layer 110 may be disposed below each of the gate electrodes 120, the first source/drain pattern 150, and the second source/drain pattern 250. The lower insulating layer 110 may surround the semiconductor pattern 210.

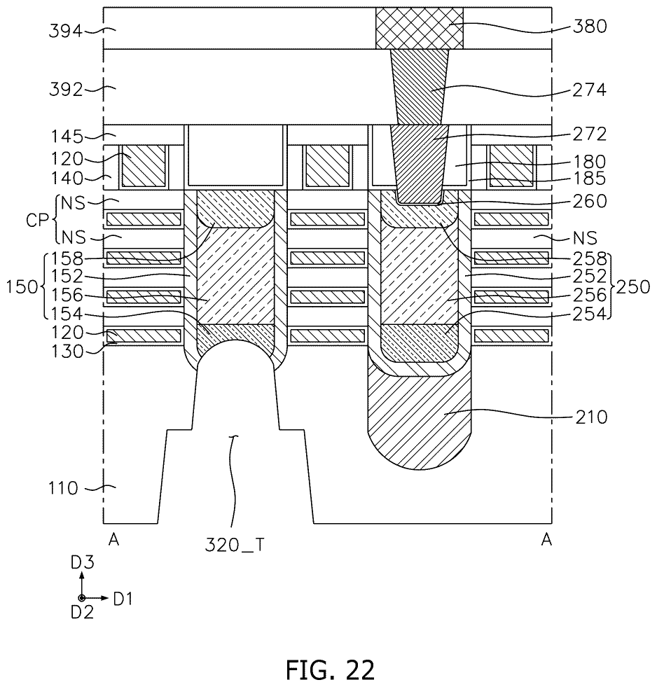

Referring to FIG. 22, a portion of the semiconductor pattern 210 may be removed, and a connection structure trench 320_T may be formed.

Specifically, the semiconductor pattern 210 disposed below the first source/drain pattern 150 may be removed. For example, a portion of the lower insulating layer 110 may be etched to expose the semiconductor pattern 210 disposed below the first source/drain pattern 150. An etching process of removing the exposed semiconductor pattern 210 may be performed to form the connection structure trench 320_T. Since the connection structure trench 320_T is formed by two etching processes, the connection structure trench 320_T may include a stepped surface. For example, during the etching process of removing the exposed semiconductor pattern 210, a portion of the first lower filling film 154 may be removed together.

Referring to FIGS. 22 and 2, the connection structure 320 may be formed on the connection structure trench 320_T. The lower wiring 300 may be formed below the connection structure 320 and the lower insulating layer 110 and the semiconductor device of FIG. 2 may be manufactured.

Although certain embodiments of the present invention have been described with reference to the accompanying drawings, those of ordinary skill in the art to which the present invention pertains will understand that the present invention may be implemented in other specific forms without changing its technical idea or essential features. Therefore, it should be understood that the embodiments described above are illustrative and non-limiting in all respects.

1. A semiconductor device, comprising:
a lower wiring pattern extending in a first direction;
a lower insulating layer disposed on the lower wiring pattern;
a channel pattern disposed on the lower insulating layer;
a gate electrode surrounding the channel pattern and extending in a second direction intersecting the first direction;
a first source/drain pattern disposed on a first side surface of the channel pattern, wherein the first source/drain pattern comprises a first lower region and a first middle region;
a second source/drain pattern disposed on a second side surface of the channel pattern, wherein the second source/drain pattern comprises a second lower region and a second middle region; and
a connection pattern formed through the lower insulating layer and connecting the lower wiring pattern and the first source/drain pattern,
wherein:
one end of the connection pattern is in contact with the first lower region,
a concentration of a dopant in the second lower region is greater than a concentration of a dopant in the second middle region,
the second source/drain pattern is disposed in a source/drain trench, and a lowermost end of the source/drain trench is located at a central portion of a bottom surface of the source/drain trench, and
the first and second middle regions are located at higher height levels than the first and second lower regions, and the first and second lower regions are located at higher height levels than the bottom surface of the source/drain trench.

2. The semiconductor device according to claim 1, wherein:
the first source/drain pattern further comprises a first liner disposed on the first side surface of the channel pattern, and the first lower region and the first middle region are surrounded by the first liner,
the second source/drain pattern further comprises a second liner disposed on the second side surface of the channel pattern, and the second lower region and the second middle region are surrounded by the second liner, and
the second liner extends along a sidewall of the source/drain trench.

3. The semiconductor device according to claim 1, further comprising a semiconductor pattern disposed below the second source/drain pattern,
wherein the semiconductor pattern is disposed in the lower insulating layer.

4. The semiconductor device according to claim 1, wherein a concentration of a dopant in the first lower region is greater than a concentration of a dopant in the first middle region.

5. The semiconductor device according to claim 1, wherein a concentration of a dopant in the first lower region is the same as the concentration of the dopant in the second lower region.

6. The semiconductor device according to claim 1, wherein:
the first source/drain pattern further comprises a first liner disposed on the first side surface of the channel pattern, and
the first liner is disposed between the channel pattern and the first lower region and between the channel pattern and the first middle region.

7. The semiconductor device according to claim 1, wherein:
the connection pattern comprises a lower source/drain contact and a silicide film, and the silicide film is disposed between the lower source/drain contact and the first source/drain pattern, and
the silicide film is in contact with the first lower region.

8. The semiconductor device according to claim 1, wherein the connection pattern comprises a lower source/drain contact disposed on the first source/drain pattern, and a lower via connecting the lower source/drain contact to the lower wiring pattern.

9. The semiconductor device according to claim 1, wherein
the second source/drain pattern further comprises an upper region disposed in the source/drain trench and disposed on the second middle region, and
a concentration of a dopant in the upper region is greater than the concentration of the dopant in the second middle region.

10. The semiconductor device according to claim 9, further comprising an upper source/drain contact disposed on the upper region,
wherein the upper region is an upper filling film.

11. A semiconductor device, comprising:
a lower wiring pattern extending in a first direction;
a lower insulating layer disposed on the lower wiring pattern;
a plurality of sheet patterns disposed on the lower insulating layer and spaced apart from each other in a direction perpendicular to an upper surface of the lower wiring pattern;
a gate electrode surrounding the plurality of sheet patterns and extending in a second direction intersecting the first direction;
a first source/drain pattern disposed on a side of the plurality of sheet patterns, wherein the first source/drain pattern comprises a first lower region, a first middle region and a first upper region, which are sequentially stacked;
a second source/drain pattern disposed spaced apart from the first source/drain pattern, wherein the second source/drain pattern comprises a second lower region, a second middle region and a second upper region, which are sequentially stacked;
a first semiconductor pattern disposed below the second source/drain pattern; and
a connection pattern formed through the lower insulating layer and connecting the lower wiring pattern and the first source/drain pattern, wherein the connection pattern is in contact with the first lower region,
wherein:
a concentration of a dopant in the first lower region is greater than a concentration of a dopant in the first middle region.

12. The semiconductor device according to claim 11, further comprising a source/drain trench, wherein:
the second source/drain pattern disposed in the source/drain trench,
the first source/drain pattern further comprises a first liner disposed on a first side surface of the plurality of sheet patterns, and the first lower region and the first middle region are surrounded by the first liner,
the second source/drain pattern further comprises a second liner disposed on a second side surface of the plurality of sheet patterns, and the second lower region and the second middle region are surrounded by the second liner,
the second liner extends along a sidewall of the source/drain trench, and
the sidewall of the source/drain trench has a wavy shape.

13. The semiconductor device according to claim 11, wherein
the second lower region comprises a first portion, and a second portion protruding from the first portion in a direction perpendicular to the upper surface of the lower wiring pattern, and
the second portion of the second lower region overlaps with at least some of the plurality of sheet patterns in the first direction.

14. The semiconductor device according to claim 11, further comprising a second semiconductor pattern disposed between the lower insulating layer and the gate electrode.

15. The semiconductor device according to claim 11, wherein
the connection pattern comprises a lower source/drain contact disposed on the first source/drain pattern, and a lower via connecting the lower source/drain contact to the lower wiring pattern, and
a distance from the upper surface of the lower wiring pattern to an upper surface of the lower via is greater than a distance from the upper surface of the lower wiring pattern to a lowermost portion of the first semiconductor pattern.

16. The semiconductor device according to claim 11, wherein the connection pattern comprises a conductive barrier film, and a lower source/drain contact and a lower via disposed in the conductive barrier film.

17. The semiconductor device according to claim 11, wherein
the plurality of sheet patterns and the first source/drain pattern are disposed on a PMOS transistor region,
the dopant of the first lower region includes at least one of boron, aluminum, gallium, and indium, and
the dopant of the first middle region includes at least one of boron, aluminum, gallium, and indium.

18. The semiconductor device according to claim 11, wherein
the first lower region and the first middle region comprise germanium, and
a concentration of germanium in the first lower region is greater than a concentration of germanium in the first middle region.

19. The semiconductor device according to claim 11, wherein:
a concentration of a dopant in the first upper region is greater than a concentration of a dopant in the first middle region, and
the first lower region, the first middle region, the first upper region, the second lower region, the second middle region, and the second upper region may be a first lower filling film, a first middle filling film, a first upper filling film, a second lower filling film, a second middle filling film, and a second upper filling film.

20. A semiconductor device, comprising:
a lower wiring pattern extending in a first direction;
a lower insulating layer disposed on the lower wiring pattern;
a plurality of sheet patterns disposed on the lower insulating layer and spaced apart from each other in a direction perpendicular to an upper surface of the lower wiring pattern;
a gate electrode surrounding the plurality of sheet patterns and extending in a second direction intersecting the first direction;
a first source/drain pattern disposed on a side of the plurality of sheet patterns, wherein the first source/drain pattern comprises a first liner, a first lower region, a first middle region, and a first upper region, wherein the first lower region, the first middle region, and the first upper region are sequentially stacked on the first liner;
a second source/drain pattern disposed spaced apart from the first source/drain pattern, wherein the second source/drain pattern comprises a second liner, a second lower region, a second middle region, and a second upper region, wherein the second lower region, the second middle region, and the second upper region sequentially stacked on the second liner;
a semiconductor pattern disposed below the second source/drain pattern; and
a connection pattern formed through the lower insulating layer and connecting the lower wiring pattern and the first source/drain pattern, wherein
one end of the connection pattern is disposed on the first lower region,
a concentration of a dopant in the first upper region is greater than a concentration of a dopant in the first middle region,
a concentration of a dopant in the first lower region is greater than the concentration of the dopant in the first middle region,
the concentration of the dopant in the first lower region is the same as a concentration of a dopant in the second lower region,
the first lower region is formed in a lower portion of a space surrounded by the first liner, and
the second lower region is formed in a lower portion of a space surrounded by the second liner.
